(19) United States
(12) Patent Application Publication
(10) Pub. No.: US 2026/0271759 A1
(43) Pub. Date: Sep. 10, 2026

(54) Semiconductor Device, Semiconductor Package, and Semiconductor Packaging Method

(71) Applicant: JIASHAN FUDAN RESEARCH INSTITUTE, Jiaxing (CN)

(72) Inventors: Bao ZHU, Jiaxing (CN); Wenlong XU, Jiaxing (CN); Shijin DING, Jiaxing (CN); Bocheng ZHANG, Jiaxing (CN); Lilong ZHANG, Jiaxing (CN); Nianwen YU, Jiaxing (CN); Wei ZHANG, Jiaxing (CN)

(73) Assignee: JIASHAN FUDAN RESEARCH INSTITUTE, Jiaxing (CN)

(21) Appl. No.: 19/358,260

(22) Filed: Oct. 14, 2025

(30) Foreign Application Priority Data
Mar. 6, 2025 (CN) 202510258826.6

(51) Int. Cl. H10W 70/685; H10W 70/05; H10W 90/26

(52) U.S. Cl. CPC H10W 70/685; H10W 70/05; H10W 90/26

(57) ABSTRACT

The present invention relates to the field of semiconductor packaging, and provides a semiconductor device, a semiconductor package, and a semiconductor packaging method. The semiconductor device is for use in a semiconductor package and includes: a plurality of stacked semiconductor chips, wherein a current semiconductor chip is stacked on a lower semiconductor chip; a substrate of the current semiconductor chip has an opposing first surface and second surface; the first surface is configured to provide an attachment surface for interconnect layers; the second surface is configured to abut against an interconnect layer at a top portion of the lower semiconductor chip. This structure is configured to reduce interlayer gaps and interlayer height fluctuations, thereby decreasing process steps for gap filling, ensuring no short circuits after packaging, and guaranteeing device performance.

### CROSS-REFERENCE

This application claims the benefit of priority from China Patent Application No. CN 202510258826.6 filed on March 6 2025, the contents of which are hereby incorporated by reference in their entirety.

### TECHNICAL FIELD

The present disclosure relates to the field of semiconductor packaging, and more particularly, to a semiconductor device, a semiconductor package, and a semiconductor packaging method.

### BACKGROUND ART

Semiconductor devices are typically fabricated using diverse semiconductor materials, processes, and geometric structures, resulting in a wide variety of devices with distinct functions and applications. These devices often require electrical connections between conductive materials across multiple layers to achieve device interconnection and deliver desired performance. Semiconductor devices continue to evolve toward smaller size, higher speed, and greater efficiency, necessitating continuous innovation and optimization in manufacturing processes. However, a series of technical challenges remain unresolved during semiconductor device fabrication. In conventional solutions, interconnect layers are formed by physical deposition. When implementing cross-layer interconnection between devices, through-silicon vias (TSVs) are commonly employed. This approach, however, requires strict control over inter-layer alignment and via drilling precision. Insufficient precision can readily cause device failure, while the use of insulating fill materials to seal gaps may obstruct cross-layer conduction, further degrading device performance. Therefore, there is an urgent need for a semiconductor device, a semiconductor package, and a semiconductor packaging method to address the above issues.

### SUMMARY OF THE INVENTION

An object of the present disclosure is to provide a semiconductor device, a semiconductor package, and a semiconductor packaging method. The structure is configured to reduce interlayer height fluctuation in multi-layer chips to ensure performance of semiconductor devices.

In a first aspect, the present disclosure provides a semiconductor device for use inside a semiconductor package. The semiconductor device includes a plurality of stacked semiconductor chips, wherein a current semiconductor chip is stacked on a lower semiconductor chip; each semiconductor chip includes a plurality of interconnect layers, a plurality of insulating layers, and a substrate; the interconnect layers are configured to provide conductive first regions and second regions; contours of etching trenches in adjacent interconnect layers among N interconnect layers are non-overlapping along a stacking direction, where N is a positive integer greater than 2. The insulating layers are disposed between adjacent interconnect layers and configured to provide insulating dielectrics. The substrate of the current semiconductor chip has an opposing first surface and second surface. The first surface is configured to provide an attachment surface for the interconnect layers. The second surface is configured to abut against an interconnect layer at a top portion of the lower semiconductor chip.

Optionally, the interconnect layers in each semiconductor chip are arranged in M layers, where M is greater than or equal to N. When M equals N, contours of etching trenches in the N interconnect layers are all non-overlapping along the stacking direction.

Optionally, when M is greater than N, contours of etching trenches in interconnect layers within the N layers partially overlap with contours in interconnect layers outside the N layers.

Optionally, each semiconductor chip has interconnect layers comprising an opposing first edge and second edge. In two adjacent interconnect layers of each chip, etching trenches are respectively disposed adjacent to the first edge and the second edge, such that first regions and second regions alternately overlap between adjacent interconnect layers.

In a second aspect, the present disclosure provides a semiconductor package including: the semiconductor device according to any one of the first aspect; a first conductive terminal configured to connect first regions of interconnect layers in each semiconductor chip; and a second conductive terminal configured to connect second regions of the interconnect layers in each semiconductor chip. The first conductive terminal and the second conductive terminal are mutually isolated.

In a third aspect, the present disclosure provides a semiconductor packaging method for forming the semiconductor device according to any one of the first aspect. The method includes: S1: providing a substrate and forming interconnect regions at portions requiring conductor leads; S2: performing an etching process on non-interconnect regions of the surface layer not requiring conductor leads, such that the non-interconnect regions are partitioned by etching trenches into first regions and second regions; S3: forming an insulating layer on a surface of an interconnect layer, and forming another interconnect layer on an upper surface of the insulating layer; S4: repeating S2-S3 a plurality of times, then performing S2 once more to form a semiconductor chip, wherein contours of etching trenches in adjacent interconnect layers among the N interconnect layers are non-overlapping along a stacking direction, N being a positive integer greater than 2; S5: repeating S1-S4 L times, L being a positive integer greater than 1, and stacking the L semiconductor chips to form the semiconductor device.

Optionally, the method further includes performing a thinning process on the semiconductor chips, and stacking the L thinned semiconductor chips to form the semiconductor device.

Optionally, the method further includes cutting or polishing edges of the stacked interconnect layers such that the first regions and second regions of the interconnect layers in the semiconductor chips are exposed.

Optionally, the method further includes forming a first conductive terminal to connect the first regions in the interconnect layers, and forming a second conductive terminal to connect the second regions in the interconnect layers.

Optionally, the interconnect layers and the insulating layers are formed by at least one process selected from atomic layer deposition and chemical vapor deposition; and the first conductive terminal and the second conductive terminal are formed by an electroplating process.

Advantageous effects of the present disclosure are as follows: when applied in semiconductor packaging, the semiconductor device includes a plurality of stacked semiconductor chips, wherein a current semiconductor chip is stacked on a lower semiconductor chip; the substrate of the current semiconductor chip has an opposing first surface and second surface; the first surface provides an attachment surface for interconnect layers, and the second surface abuts against an interconnect layer at a top portion of the lower semiconductor chip. This structure reduces inter-layer gaps and height fluctuations, thereby decreasing process steps for gap filling, ensuring no short circuits after packaging, and guaranteeing device performance. Compared with through-silicon via processes, the structure does not require precisely etching internal silicon structures, thus reducing process complexity for stacking semiconductor devices.

### DESCRIPTION OF DRAWINGS

FIG. 1 is a schematic diagram of a semiconductor device according to the present patent;

FIG. 2 is a schematic structural diagram of a semiconductor package according to the present patent;

FIG. 3 is a schematic flowchart of a semiconductor packaging method according to the present patent;

FIG. 4 is a schematic structural diagram showing an odd-numbered first interconnect layer formed on a substrate according to the present patent;

FIG. 5 is a schematic structural diagram showing an odd-numbered first etching trench formed in the odd-numbered first interconnect layer according to the present patent;

FIG. 6 is a schematic structural diagram showing a first insulating layer formed on the odd-numbered first interconnect layer according to the present patent;

FIG. 7 is a schematic structural diagram showing an odd-numbered second interconnect layer formed on the first insulating layer according to the present patent;

FIG. 8 is a schematic structural diagram showing an odd-numbered second etching trench formed in the odd-numbered second interconnect layer according to the present patent;

FIG. 9 is a schematic structural diagram showing a second insulating layer formed on the odd-numbered second interconnect layer according to the present patent;

FIG. 10 is a schematic structural diagram of a semiconductor package provided with conductive terminals according to the present patent.

### DESCRIPTION OF REFERENCE NUMERALS

1: substrate; 6: chip unit; 21: odd-numbered first interconnect layer; 22: even-numbered first interconnect layer; 31: odd-numbered second interconnect layer; 32: even-numbered second interconnect layer; 41: first insulating layer; 42: second insulating layer; 43: third insulating layer; 51: first conductive terminal; 52: second conductive terminal; 201: odd-numbered first etching trench; 202: even-numbered first etching trench; 211: high-potential region of odd-numbered first interconnect layer; 212: low-potential region of odd-numbered first interconnect layer; 221: high-potential region of even-numbered first interconnect layer; 222: low-potential region of even-numbered first interconnect layer; 301: odd-numbered second etching trench; 302: even-numbered second etching trench; 311: high-potential region of odd-numbered second interconnect layer; 312: low-potential region of odd-numbered second interconnect layer; 321: high-potential region of even-numbered second interconnect layer; and 322: low-potential region of even-numbered second interconnect layer.

### EMBODIMENTS

To make the objectives, technical solutions, and advantages of the present patent clearer, the technical solutions in the embodiments of the present patent will be described clearly and completely below with reference to the accompanying drawings. Obviously, the described embodiments are merely some of the embodiments of the present patent, rather than all of them. All other embodiments obtained by a person of ordinary skill in the art based on the embodiments of the present patent without making creative efforts shall fall within the protective scope of the present patent. Unless otherwise defined, technical or scientific terms used herein shall have the ordinary meaning as understood by a person of ordinary skill in the art to which the present patent belongs. The word “comprising” and similar words used herein mean that the elements or items preceding the word encompass the elements or items listed after the word and their equivalents, without excluding other elements or items.

Current prior art typically employs through-silicon via technology to achieve 3D packaging. However, existing etching processes for these vias, including laser etching and deep reactive ion etching, require high-precision techniques to fabricate micro-vias with high-aspect-ratio structures. This necessitates supporting high-precision etching equipment, which is often expensive, thereby increasing the cost of mass production and hindering the adoption of highly integrated packaging.

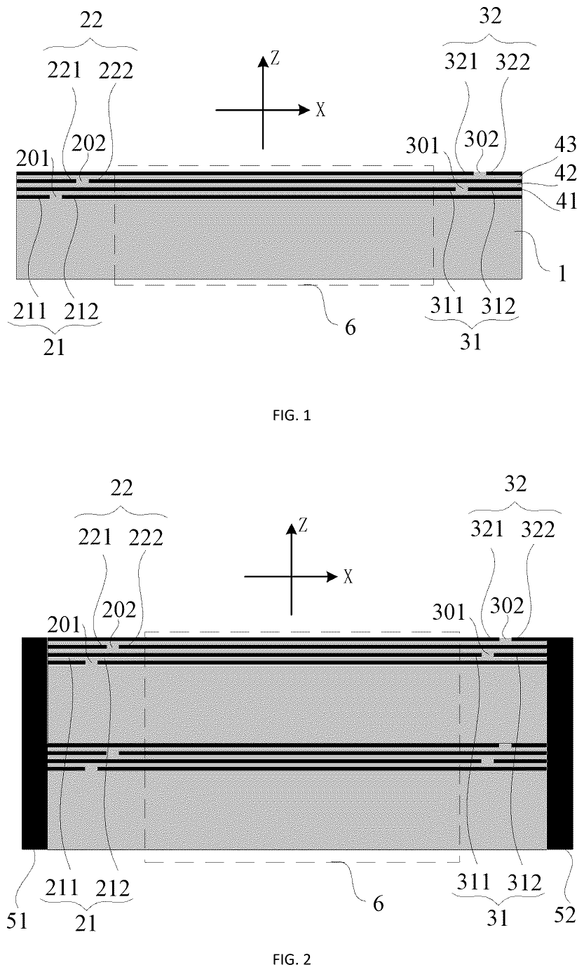

To address the problems existing in the prior art, as shown in FIG. 1, a first embodiment of the present disclosure provides a semiconductor device for use inside a semiconductor package. The device comprises: a plurality of stacked semiconductor chips, wherein a current semiconductor chip is stacked on a lower semiconductor chip; each semiconductor chip has a plurality of interconnect layers, a plurality of insulating layers, and a substrate; the interconnect layers are configured to provide conductive first regions and second regions; contours of etching trenches in adjacent interconnect layers among N interconnect layers are non-overlapping along a stacking direction, N being a positive integer greater than 2; the insulating layers are disposed between adjacent interconnect layers and configured to provide insulating dielectrics; the substrate of the current semiconductor chip has an opposing first surface and second surface; the first surface is configured to provide an attachment surface for the interconnect layers; the second surface is configured to abut against an interconnect layer at a top of the lower semiconductor chip. In the present embodiment, by having the contours of the etching trenches in adjacent interconnect layers among the N interconnect layers being non-overlapping along the stacking direction, the accumulation of height differences from etching trenches set in multiple interconnect layers to form interlayer height fluctuations is avoided. This configuration can increase the actual effective conductive area, maintain a uniform electric field between the interconnect layers, prevent excessively high local electric field strength, thereby reducing leakage current, improving the insulating performance of the insulating layers, preventing breakdown, and is conducive to enhancing the performance of the semiconductor device.

In some other specific embodiments, the stacking direction of the N interconnect layers is along a vertical direction Z, and the extension directions of the substrate 1, the interconnect layers, and the insulating layers are along a horizontal plane. The etching trenches are configured to extend gradually deeper into the interconnect layers along the vertical direction Z until contacting the substrate 1 or an insulating layer. The stacked structure of the present embodiment can disperse stress, reduce pressure on a monolithic structure, and enhance the mechanical stability of the semiconductor device.

In yet other specific embodiments, the substrate 1 in each semiconductor chip is made of a material selected from silicon, silicon oxide, zirconium oxide, hafnium oxide, germanium, silicon nitride, aluminum oxide, and gallium oxide. The interconnect layers are made of a conductive material. The insulating layers are made of an insulating material. The insulating layers are further configured to fill the etching trenches in the interconnect layers located beneath them, such that the first regions and the second regions are separated by said insulating material.

In some embodiments, the interconnect layers in each semiconductor chip are arranged as M layers, M being greater than or equal to N; when M equals N, contours of etching trenches in the N interconnect layers are all non-overlapping along the stacking direction.

In some specific embodiments, M=N=4; an odd-numbered first interconnect layer 21 is connected to the attachment surface provided by the substrate 1; a first insulating layer 41 is connected to the odd-numbered first interconnect layer 21; an odd-numbered second interconnect layer 31 is connected to the first insulating layer 41; a second insulating layer 42 is connected to the odd-numbered second interconnect layer 31; an even-numbered first interconnect layer 22 is connected to the second insulating layer 42; a third insulating layer 43 is connected to the even-numbered first interconnect layer 22; and an even-numbered second interconnect layer 32 is connected to the third insulating layer 43. By arranging the etching trenches in the N interconnect layers to be non-overlapping in the Z direction, the present embodiment achieves avoidance of accumulated height differences from etching trenches, fundamentally eliminating step differences. It increases the actual effective conductive area of the chip, maintains a uniform electric field between interconnect layers, prevents locally excessive electric field strength, thereby reducing leakage current, improving the insulating performance of the insulating layers, preventing breakdown, and is beneficial for enhancing the performance of the semiconductor device.

In some examples, the odd-numbered first interconnect layer 21 comprises an odd-numbered first etching trench 201 proximate to the negative X direction. The even-numbered first interconnect layer 22 comprises an even-numbered first etching trench 202 proximate to the negative X direction. The odd-numbered first etching trench 201 and the even-numbered first etching trench 202 are adjacent etching trenches relative to each other, and their contours are non-overlapping in the Z direction.

In other examples, the odd-numbered second interconnect layer 31 comprises an odd-numbered second etching trench 301 proximate to the X direction. The even-numbered second interconnect layer 32 comprises an even-numbered second etching trench 302 proximate to the X direction. The odd-numbered second etching trench 301 and the even-numbered second etching trench 302 are adjacent etching trenches relative to each other, and their contours are non-overlapping in the Z direction.

It is worth noting that Micro-displacement Fine Trench Patterning (MDFTP) is employed to define the positions of etching trenches in adjacent interconnect layers. This technique can achieve sub-micron or even nano-scale positioning accuracy, which is beneficial for increasing the integration level of integrated circuits.

In some embodiments, when M is greater than N, contours of etching trenches in interconnect layers within the N layers partially overlap with contours in interconnect layers outside the N layers.

In some specific embodiments, M=20 and N=10. Twenty interconnect layers and twenty insulating layers are stacked along the Z direction on the substrate 1; the contour of an etching trench in the interconnect layer at the first layer partially overlaps in the Z direction with the contour of an etching trench in the interconnect layer at the 401st layer; the contour of an etching trench in the interconnect layer at the second layer partially overlaps in the Z direction with the contour of an etching trench in the interconnect layer at the 402nd layer; and the contour of an etching trench in the interconnect layer at the tenth layer partially overlaps in the Z direction with the contour of an etching trench in the interconnect layer at the twentieth layer. By reusing etching trench positions at intervals of N interconnect layers, the present embodiment can minimize the local accumulation of etching trench height differences as much as possible, enabling the semiconductor device to achieve a higher number of layers to meet the design of high-capacity semiconductor packages. Additionally, the present embodiment increases the number of interconnect layers to M, which can further increase the effective conductive area, thereby enhancing the overall operating efficiency of the semiconductor device.

In some embodiments, each interconnect layer in the semiconductor chips has an opposing first edge and a second edge. Etching trenches in two adjacent interconnect layers are disposed proximate to the first edge and the second edge, respectively, such that the first regions and the second regions in the adjacent interconnect layers alternately overlap.

In some specific embodiments, the first edge is located at the negative X direction and the second edge is located at the X direction. In some examples, the odd-numbered first interconnect layer low-potential region 212, the odd-numbered second interconnect layer high-potential region 311, the even-numbered first interconnect layer low-potential region 222, and the even-numbered second interconnect layer high-potential region 321 are alternately overlapped from bottom to top in sequence. In other specific embodiments, the first edge is located at the X direction and the second edge is located at the negative X direction. By disposing the etching trenches in two adjacent interconnect layers proximate to the first edge and the second edge respectively, this embodiment enables better utilization of space, further increases the effective conductive area, and consequently improves operating efficiency.

In some embodiments, the semiconductor device includes a chip unit 6; the chip unit 6 is located in a central region of the semiconductor device; the odd-numbered first etching trench 201 is located at the negative X direction of the chip unit 6; and the odd-numbered second etching trench 301 is located at the X direction of the chip unit 6.

In some specific embodiments, the chip unit 6 is a storage chip unit. The storage chip unit includes a Static Random Access Memory (SRAM), a Dynamic Random Access Memory (DRAM), or other types of non-volatile memory.

In other specific embodiments, the chip unit 6 is a logic chip unit. The logic chip unit includes an Arithmetic Logic Unit (ALU), a microprocessor core, a Digital Signal Processor (DSP), or an Application-Specific Integrated Circuit (ASIC) for executing specific algorithms.

As shown in FIG. 2, a second embodiment provides a semiconductor package, including: the semiconductor device according to any one of the aforementioned embodiments; a first conductive terminal 51 configured to connect the first regions of the interconnect layers in each semiconductor chip; a second conductive terminal 52 configured to connect the second regions of the interconnect layers in each semiconductor chip; wherein the first conductive terminal 51 and the second conductive terminal 52 are not connected to each other.

In some specific embodiments, the first conductive terminal 51 is configured to connect to a high-potential terminal, and the second conductive terminal 52 is configured to connect to a low-potential terminal. When a potential difference exists between the high-potential terminal and the low-potential terminal, an electric field is formed between the first regions and the second regions. In other specific embodiments, the first conductive terminal 51 is configured to connect to a low-potential terminal, and the second conductive terminal 52 is configured to connect to a high-potential terminal. It is noteworthy that this embodiment achieves a parallel connection of adjacent interconnect layers by providing the disconnected first conductive terminal 51 and second conductive terminal 52, which is advantageous for increasing the area of the terminals. This benefit, combined with the effective utilization of space and the parallel connection of multiple interconnect layers, enhances the integration level of the semiconductor device.

In some examples, the number of interconnect layers is even, and charges are stored through the alternating insulating layers and interconnect layers. In other examples, the number of interconnect layers is odd, and the interconnect layer at the top level is not connected to the first conductive terminal 51 or the second conductive terminal 52, providing shielding. This design can reduce electromagnetic interference between the semiconductor device and other components, especially in high-frequency applications. The shielding effect of the top interconnect layer helps maintain stable performance of the semiconductor device and reduces electromagnetic interference to the external environment.

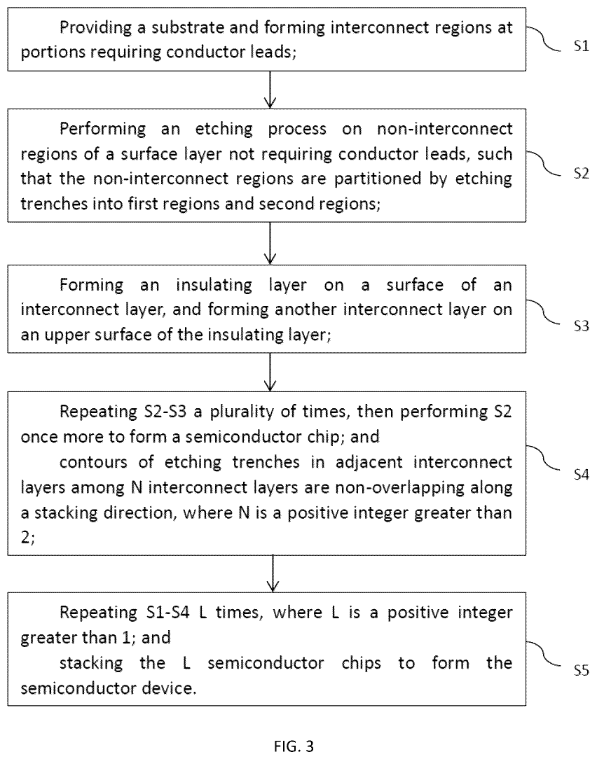

As shown in FIG. 3, a third embodiment provides a semiconductor packaging method for forming the semiconductor device according to any one of the aforementioned embodiments, comprising: S1: providing a substrate 1 and forming an interconnect layer at portions requiring conductor leads; S2: performing an etching process on non-interconnect regions of a surface layer not requiring conductor leads, such that the non-interconnect regions are partitioned by etching trenches into first regions and second regions; S3: forming an insulating layer on a surface of the interconnect layer, and forming another interconnect layer on an upper surface of the insulating layer; S4: repeating S2-S3 a plurality of times, then performing S2 once more to form a semiconductor chip, wherein contours of etching trenches in adjacent interconnect layers among N interconnect layers are non-overlapping along the stacking direction, N being a positive integer greater than 2; and S5: repeating S1-S4 L times, L being a positive integer greater than 1, and stacking the L semiconductor chips to form the semiconductor device.

It is noteworthy that the interconnect layers and the insulating layers are formed by at least one process selected from Atomic Layer Deposition (ALD) and Chemical Vapor Deposition (CVD). Through the repeated execution of steps S2 and S3, the present embodiment achieves a layer-by-layer alternating accumulation of the multilayer interconnect layer and insulating layer structure by depositing new layers based on the previous interconnect layer and insulating layer each time. This process demonstrates high repeatability and control precision, supporting large-scale industrial production of complex multilayer structures.

In some embodiments, S5 further comprises: performing a thinning process on the semiconductor chips, and stacking the L thinned semiconductor chips to form the semiconductor device. It is noteworthy that the present embodiment, by stacking semiconductor chips, resets local variations in layer height, avoids excessive layer height fluctuations that could reduce the effective conductive area, improves the uniformity of the electric field between interconnect layers, is conducive to reducing leakage current, enhances the insulating performance of the insulating layers, avoids the risk of breakdown, and ensures the performance of the semiconductor device assembly.

More specifically, when performing the thinning process on the substrate bottom surface of each semiconductor chip, the thinning process is applied to the second surface of the substrate therein to thin the substrate to 80-100 micrometers. The thinning process is mechanical grinding, chemical mechanical polishing, or etching. By thinning the substrate in the semiconductor chips, this embodiment minimizes the volume proportion of substrates in the semiconductor device assembly as much as possible, allowing limited on-chip space to accommodate more interconnect layers.

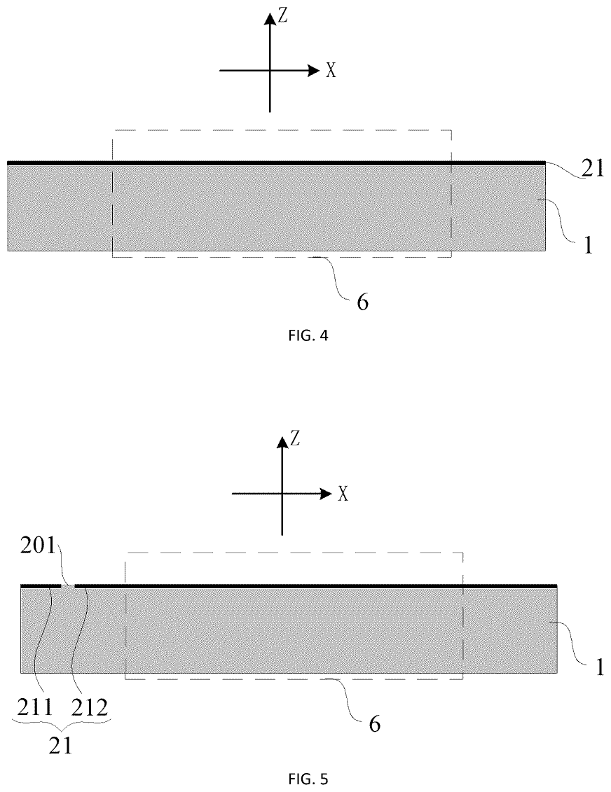

As shown in FIG. 4, in a first example, five silicon substrates 1 with a size of 2 cm*2 cm are patterned using a reactive ion etching process. S1 includes: depositing a 20-nanometer-thick titanium nitride (TIN) layer as an odd-numbered first interconnect layer 21 on a surface of a silicon wafer using an atomic layer deposition process.

As shown in FIG. 5, the first execution of S2 further includes: etching the odd-numbered first interconnect layer 21 at a first edge located at a negative X direction to form an odd-numbered first etching trench 201, thereby partitioning the odd-numbered first interconnect layer 21 into an odd-numbered first interconnect layer high-potential region 211 and an odd-numbered first interconnect layer low-potential region 212.

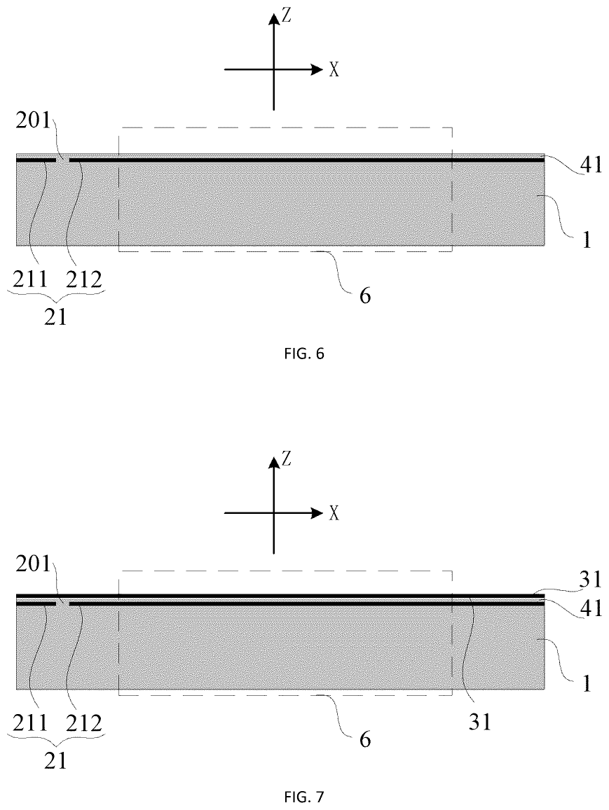

As shown in FIG. 6, the first execution of S3 further includes: S31, depositing a 10-nm-thick hafnium-zirconium oxide (HfZrO) antiferroelectric material as a first insulating layer 41 on a surface of the odd-numbered first interconnect layer 21 using an atomic layer deposition (ALD) process. As shown in FIG. 7, depositing a 40-nm-thick titanium nitride (TiN) layer as an odd-numbered second interconnect layer 31 on the first insulating layer 41 using an atomic layer deposition (ALD) process.

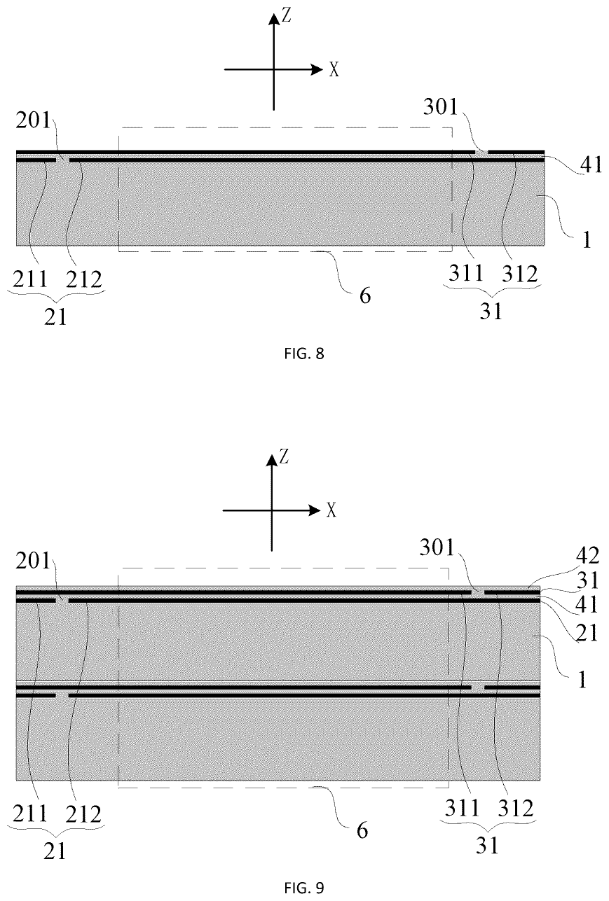

As shown in FIG. 8, the second execution of S2 further includes: S41, etching the odd-numbered second interconnect layer 31 at a second edge located at an X direction to form an odd-numbered second etching trench 301, thereby partitioning the odd-numbered second interconnect layer 31 into an odd-numbered second interconnect layer high-potential region 311 and an odd-numbered second interconnect layer low-potential region 312.

As shown in FIG. 9, the second execution of S3 further includes: S42, depositing a 10-nm-thick silicon oxide layer as a second insulating layer 42 on a surface of the odd-numbered second interconnect layer 31 using a chemical vapor deposition process. Depositing a 20-nm-thick titanium nitride layer as an even-numbered first interconnect layer 22 on the second insulating layer 42 using an atomic layer deposition process.

The third execution of S2 further includes: S43, etching the even-numbered first interconnect layer 22 at a first edge located at the X direction to form an even-numbered first etching trench 202, thereby partitioning the even-numbered first interconnect layer 22 into an even-numbered first interconnect layer high-potential region 221 and an even-numbered first interconnect layer low-potential region 222.

The third execution of S3 further includes: S44, depositing a 10-nm-thick hafnium-zirconium oxide (HfZrO) antiferroelectric material as a third insulating layer 43 on a surface of the even-numbered first interconnect layer 22 using an atomic layer deposition process. Depositing a 50-nm-thick titanium nitride layer as an even-numbered second interconnect layer 32 on the third insulating layer 43 using an atomic layer deposition (ALD) process.

The fourth execution of S2 further includes: S45, etching the even-numbered second interconnect layer 32 at a second edge located at the X direction to form an even-numbered second etching trench 302, thereby partitioning the even-numbered second interconnect layer 32 into an even-numbered second interconnect layer high-potential region 321 and an even-numbered second interconnect layer low-potential region 322.

The fourth execution of S3 further includes: S46, depositing a 10-nm-thick silicon oxide (SiO2) layer as a fourth insulating layer on a surface of the even-numbered second interconnect layer 32 using a chemical vapor deposition process.

It is noteworthy that the last execution of S2 on the current substrate further includes: etching an interconnect layer at a top surface to form a top surface interconnect layer etching trench, partitioning the interconnect layer at the top surface into a top surface high-potential region and a top surface low-potential region.

Using the fourth insulating layer as a substrate 1, the aforementioned S1-S46 are repeated ten times to form a semiconductor chip of the first example. The five semiconductor chips are thinned until the substrates reach 80 micrometers, and finally a liquid metal paste is prepared on the substrates to stack the five semiconductor chips, forming the semiconductor device.

The present example, by combining atomic layer deposition and chemical vapor deposition, precisely controls the thickness and quality of insulating layers (e.g., zirconium oxide, hafnium oxide), ensures the effective utilization of high-dielectric-constant materials, and consequently improves the energy density and efficiency of the semiconductor device. Selecting titanium nitride as the material for the interconnect layers benefits from its excellent conductivity and thermal stability. Combined with high-dielectric-constant materials, it significantly enhances the high-frequency performance and thermal stability of the device, meeting the requirements of high-performance electronic equipment.

In a second example, twenty silicon substrates 1 with a size of 1 cm*1 cm are patterned using a reactive ion etching process. A 400-nanometer-thick tungsten layer is deposited as an odd-numbered first interconnect layer 21 on a surface of a silicon wafer using an atomic layer deposition process.

As shown in FIG. 5, the first execution of S2 further includes: etching the odd-numbered first interconnect layer 21 at a first edge located at a negative X direction to form an odd-numbered first etching trench 201, thereby partitioning the odd-numbered first interconnect layer 21 into an odd-numbered first interconnect layer high-potential region 211 and an odd-numbered first interconnect layer low-potential region 212.

As shown in FIG. 6, the first execution of S3 further includes: S31, depositing a 20-nm-thick silicon oxide layer as a first insulating layer 41 on a surface of the odd-numbered first interconnect layer 21 using a chemical vapor deposition process. As shown in FIG. 7, depositing a 200-nm-thick tungsten layer as an odd-numbered second interconnect layer 31 on the first insulating layer 41 using a chemical vapor deposition process.

As shown in FIG. 8, the second execution of S2 further includes: S41, etching the odd-numbered second interconnect layer 31 at a second edge located at an X direction to form an odd-numbered second etching trench 301, thereby partitioning the odd-numbered second interconnect layer 31 into an odd-numbered second interconnect layer high-potential region 311 and an odd-numbered second interconnect layer low-potential region 312.

As shown in FIG. 9, the second execution of S3 further includes: S42, depositing a 10-nm-thick silicon oxide layer as a second insulating layer 42 on a surface of the odd-numbered second interconnect layer 31 using a chemical vapor deposition process. Depositing a 400-nm-thick tungsten layer as an even-numbered first interconnect layer 22 on the second insulating layer 42.

The third execution of S2 further includes: S43, etching the even-numbered first interconnect layer 22 at a first edge located at the X direction to form an even-numbered first etching trench 202, thereby partitioning the even-numbered first interconnect layer 22 into an even-numbered first interconnect layer high-potential region 221 and an even-numbered first interconnect layer low-potential region 222.

The third execution of S3 further includes: S44, depositing a 20-nm-thick silicon oxide layer as a third insulating layer 43 on a surface of the even-numbered first interconnect layer 22 using a chemical vapor deposition process. Depositing a 200-nm-thick tungsten layer as an even-numbered second interconnect layer 32 on the third insulating layer 43 using a chemical vapor deposition process.

The fourth execution of S2 further includes: S45, etching the even-numbered second interconnect layer 32 at a second edge located at the X direction to form an even-numbered second etching trench 302, thereby partitioning the even-numbered second interconnect layer 32 into an even-numbered second interconnect layer high-potential region 321 and an even-numbered second interconnect layer low-potential region 322.

The fourth execution of S 3 further includes: S 46, depositing a 10-nm-thick silicon oxide layer as a fourth insulating layer on a surface of the even-numbered second interconnect layer 32 using a chemical vapor deposition process.

Using the fourth insulating layer as a substrate 1, the aforementioned steps S1-S46 are repeated fifteen times to form a semiconductor chip of the second example. The twenty semiconductor chips are thinned until the substrates reach 100 micrometers, and finally, an inorganic adhesive is spin-coated onto the substrates to stack and fix the twenty semiconductor chips, forming the semiconductor device.

Compared to other metals and alloys, tungsten features higher electrical conductivity and better corrosion resistance. This not only enhances the conductive performance of the interconnect layers but may also improve the overall stability and service life of the device. The initial use of a chemical vapor deposition process in S3 to deposit a 20-nm-thick silicon oxide layer as the first insulating layer 41, along with subsequent variations in insulating layer thickness (e.g., the 100-nm-thick silicon oxide for the second insulating layer 42), enables optimization of chip integration level and leakage current by adjusting different dielectric materials and their thicknesses. This aims to achieve either higher integration density or lower leakage current goals.

In some embodiments, S4 further includes S45: cutting or polishing edges of the stacked interconnect layers such that the first regions and the second regions of the interconnect layers are exposed.

In some specific embodiments, edges of the stacked interconnect layers are first cut, and then the edges are polished. This ensures that the first regions of the interconnect layers present a flat cross-section at the first edge on the negative X direction side, while simultaneously, the second regions of the interconnect layers present a flat cross-section at the second edge on the X direction side. By cutting and subsequently polishing edges of the stacked interconnect layers, the present embodiment ensures that the first regions and the second regions present flat cross-sections at the edges on the negative X direction side and the X direction side, respectively. This treatment improves edge neatness of the interconnect layer structure, reduces risks of electric field concentration or short circuits caused by rough edges, and enhances the reliability and electrical performance of the device.

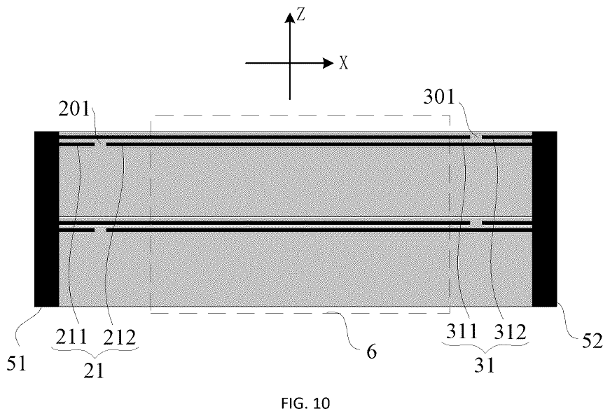

As shown in FIG. 10, in some embodiments, S5 is further included: forming a first conductive terminal 51 to connect the first regions in the interconnect layers, and forming a second conductive terminal 52 to connect the second regions in the interconnect layers.

It is noteworthy that filler materials in prior art require good fluidity and wettability, along with appropriate process conditions. The filling process needs to be highly efficient and cost-effective while ensuring no voids within the metal core and no delamination or cracking at the interface with the barrier layer. Depositing a high-quality metal seed layer on sidewalls of through-silicon vias (TSVs) is a notably difficult task, which directly affects the filling quality and overall reliability of TSVs. This difficulty is further exacerbated as aperture sizes decrease and aspect ratios increase.

In some comparative examples, a copper electroplating solution may be employed for terminal formation. However, copper electroplating presents significant challenges, requiring consistent growth rates at the top, middle, and bottom of the vias. This necessitates not only a high-quality seed layer but also longer processing times and complex process conditions, and it is susceptible to contamination.

In some specific embodiments of the present application, a graphite paste or a silver paste is used to form the first conductive terminal 51 and the second conductive terminal 52 through electroplating. This embodiment utilizes conductive terminals formed by electroplating with graphite or silver paste to significantly enhance the electrical conductivity of interconnections between interconnect layers, ensure efficient current transmission, and reduce resistive losses, which is particularly critical for improving the overall electrical performance of the semiconductor device. Both graphite and silver materials offer good conductivity and stability. The formed terminals can effectively mitigate the impact of environmental factors on the electrical connection parts, increasing the long-term stability and durability of the device. Employing an electroplating process to deposit and form the conductive terminals allows for precise control over the thickness and uniformity of the deposited layer, is suitable for batch production, can simplify the manufacturing process of the conductive terminals, and improves production efficiency while reducing costs.

In the aforementioned embodiments, the liquid metal paste or the inorganic adhesive, after solidification, is used to adhere adjacent semiconductor chips. In some examples, the liquid metal paste is defined as the interconnect layer participating in connecting to the first conductive terminal 51 or the second conductive terminal 52. This example fully leverages the insulating properties of the substrate and the conductive properties of the liquid metal, increases the effective conductive area, and further enhances the operating efficiency of the semiconductor package.

The process flow of prior art is relatively complex, involving multiple process steps including via etching, insulating layer deposition, seed layer deposition, and electroplating filling. These steps require close coordination, and any error in a single step could lead to failure of the entire product. In contrast, the present application, by using graphite paste or silver paste for electroplating to form the conductive terminals, not only simplifies the process flow and reduces production costs but also significantly improves the reliability and electrical performance of the semiconductor device.

Although the embodiments of the present invention have been described in detail above, it will be obvious to those skilled in the art that various modifications and variations can be made to these embodiments. However, it is understood that such modifications and variations fall within the scope and spirit of the present invention described in the claims. Furthermore, the present invention described herein may have other embodiments and can be implemented or realized in various ways.

1. A semiconductor device for use inside a semiconductor package, wherein:
a plurality of stacked semiconductor chips are comprised, wherein a current semiconductor chip is stacked on a lower semiconductor chip;
each semiconductor chip has N interconnect layers, a plurality of insulating layers, and a substrate, N being a positive integer greater than 2;
the interconnect layers are configured to provide conductive first regions and second regions partitioned by etching trenches;
along a stacking direction, the N interconnect layers comprise odd-numbered first interconnect layers, even-numbered first interconnect layers, odd-numbered second interconnect layers, and even-numbered second interconnect layers; and each interconnect layer in the semiconductor chips has an opposing first edge and second edge;
the odd-numbered first interconnect layers comprise odd-numbered first etching trenches formed therein; the even-numbered first interconnect layers comprise even-numbered first etching trenches formed therein; and contours of the odd-numbered first etching trenches and the even-numbered first etching trenches are non-overlapping along the stacking direction;
the odd-numbered second interconnect layers comprise odd-numbered second etching trenches formed therein; the even-numbered second interconnect layers comprise even-numbered second etching trenches formed therein; and contours of the odd-numbered second etching trenches and the even-numbered second etching trenches are non-overlapping along the stacking direction;
the odd-numbered first etching trenches and the even-numbered first etching trenches are proximate to the first edge; and the odd-numbered second etching trenches and the even-numbered second etching trenches are proximate to the second edge;
the insulating layers are disposed between adjacent interconnect layers and configured to provide insulating dielectrics; and
the substrate of the current semiconductor chip has an opposing first surface and second surface; the first surface is configured to provide an attachment surface for the interconnect layers; and the second surface is configured to abut against an interconnect layer at a top portion of the lower semiconductor chip.

2. The semiconductor device according to claim 1, wherein:
the interconnect layers in each semiconductor chip are arranged as M layers, M being greater than or equal to N; when M equals N, contours of etching trenches in the N interconnect layers are all non-overlapping along the stacking direction.

3. The semiconductor device according to claim 2, wherein:
when M is greater than N, contours of etching trenches in interconnect layers within the N layers partially overlap with contours in interconnect layers outside the N layers.

4. A semiconductor package, comprising the semiconductor device according to claim 1; and
first conductive terminal configured to connect first regions of interconnect layers in each semiconductor chip; second conductive terminal configured to connect second regions of the interconnect layers in each semiconductor chip; wherein the first conductive terminal and the second conductive terminal are mutually isolated.

5. A semiconductor packaging method for forming the semiconductor device according to claim 1, comprising:
S1: providing a substrate and forming interconnect regions at portions requiring conductor leads;
S2: performing an etching process on non-interconnect regions of a surface layer not requiring conductor leads, such that the non-interconnect regions are partitioned by etching trenches into first regions and second regions;
S3: forming an insulating layer on a surface of an interconnect layer, and forming another interconnect layer on an upper surface of the insulating layer;
S4: repeating S2-S3 a plurality of times, then performing S2 once more to form a semiconductor chip, wherein: contours of an odd-numbered first etching trench and an even-numbered first etching trench in the N interconnect layers are non-overlapping along the stacking direction; and contours of an odd-numbered second etching trench and an even-numbered second etching trench in the N interconnect layers are non-overlapping along the stacking direction, N being a positive integer greater than 2;
S5: repeating S1-S4 L times, L being a positive integer greater than 1, and stacking the L semiconductor chips to form the semiconductor device.

6. The semiconductor packaging method according to claim 5, wherein S5 further comprises: performing a thinning process on the semiconductor chips, and stacking the L thinned semiconductor chips to form the semiconductor device.

7. The semiconductor packaging method according to claim 5, wherein S4 further comprises: cutting or polishing edges of the stacked interconnect layers such that the first regions and second regions of the interconnect layers in the semiconductor chips are exposed.

8. The semiconductor packaging method according to claim 7, further comprising: forming a first conductive terminal to connect the first regions in the interconnect layers, and forming a second conductive terminal to connect the second regions in said interconnect layers.

9. The semiconductor packaging method according to claim 8, wherein the interconnect layers and the insulating layers are formed by at least one process selected from atomic layer deposition and chemical vapor deposition; and the first conductive terminal and the second conductive terminal are formed by an electroplating process.
